(19) United States
(12) Patent Application Publication
(10) Pub. No.: US 2025/0366358 A1
(43) Pub. Date: Nov. 27, 2025

(54) ELECTRONIC DEVICE, DISPLAY DEVICE, AND MANUFACTURING METHOD THEREOF

(71) Applicant: Samsung Display Co., LTD., Yongin-si (KR)

(72) Inventors: JUNMO JI, Yongin-si (KR); YONGKWON SOH, Yongin-si (KR); Junsu LEE, Yongin-si (KR)

(21) Appl. No.: 19/059,908

(22) Filed: Feb. 21, 2025

(30) Foreign Application Priority Data
May 27, 2024 (KR) 10-2024-0068648

(51) Int. Cl. H10K 59/88; H10K 59/12; H10K 59/80; H10K 102/00

(52) U.S. Cl. CPC H10K 59/88; H10K 59/1201; H10K 59/8722; H10K 2102/311

(57) ABSTRACT

A display device includes a display panel including a first area, a second area, and a bending area between the first area and the second area, a driving integrated circuit (IC) disposed on the second area, and an IC cover layer disposed on the driving IC, in which the IC cover layer includes a first insulating tape, a second insulating tape disposed on the first insulating tape, and a conductive tape disposed between the first insulating tape and the second insulating tape, and a recognition pattern is defined in one of the first insulating tape and the second insulating tape.

This application claims priority to Korean Patent Application No. 10-2024-0068648, filed on May 27, 2024, and all the benefits accruing therefrom under 35 U.S.C. § 119, the content of which in its entirety is herein incorporated by reference.

### BACKGROUND

### (1) Field

Embodiments of the disclosure described herein relate to a display device and a manufacturing method thereof.

### (2) Description of the Related Art

An electronic device such as a smart phone, a digital camera, a laptop computer, a navigation system, and a smart television that provide images to a user may include a display device for displaying images. The display device generates images and provides the images to a user through a display screen.

Recently, with the development of the technology of a display device, various types of display device are being developed. For example, a variety of flexible display devices that may be transformed into the shape of a curved surface, be folded, or rolled are being developed. Flexible display devices that may be transformed into various shapes are easily carried and improve user convenience.

The display device typically includes a display panel which displays an image and a driver disposed on the display panel. The display panel may include a first area, a second area, and a bending area between the first area and the second area. The first area may include a plurality of pixels that are driven by the driver and display an image. The first area may be folded based on a folding axis. The driver may be mounted on the second area, and the bending area may be bent in a way such that the second area is disposed under the first area. Accordingly, the driver may be disposed under the first area and may not be visible from the outside.

### SUMMARY

Embodiments of the disclosure provide a display device including a stacked structure in which a recognition pattern is capable of being easily recognized, and a manufacturing method of the same.

According to an embodiment of the disclosure, a display device includes a display panel including a first area, a second area, and a bending area between the first area and the second area, a driving integrated circuit (IC) disposed on the second area, and an IC cover layer disposed on the driving IC, in which the IC cover layer includes a first insulating tape, a second insulating tape disposed on the first insulating tape, and a conductive tape disposed between the first insulating tape and the second insulating tape, and a recognition pattern is defined in one of the first insulating tape and the second insulating tape.

In an embodiment, the recognition pattern may include a quick response (QR) pattern.

In an embodiment, the first insulating tape may include a first base layer, and a first coating layer disposed on the first base layer, and the recognition pattern may be defined in the first coating layer.

In an embodiment, a first opening overlapping the recognition pattern may be defined in the conductive tape.

In an embodiment, a second opening overlapping the recognition pattern may be defined in the second insulating tape.

In an embodiment, when viewed on a plane, each of the first opening and the second opening may have a larger area than the recognition pattern.

In an embodiment, the conductive tape may include a conductive layer disposed on the first insulating tape, and a second coating layer disposed on the conductive layer.

In an embodiment, each of the first coating layer and the second coating layer may has a black color.

In an embodiment, the first insulating tape may further include a first adhesive layer disposed between the second area and the first base layer, and the conductive tape may further include a second adhesive layer disposed between the conductive layer and the first coating layer.

In an embodiment, the second insulating tape may include a second base layer, and a third adhesive layer disposed between the second base layer and the second coating layer.

In an embodiment, the first insulating tape and the conductive tape may extend further outward than the second insulating tape.

In an embodiment, the conductive tape may include a conductive layer disposed on the first insulating tape, and an insulating layer disposed between the conductive layer and the second insulating tape, and the second insulating tape may include a base layer, and a coating layer disposed on the base layer, where the recognition pattern is defined in the coating layer.

In an embodiment, The conductive tape may include a conductive layer disposed on the first insulating tape, and a first coating layer disposed on the conductive layer, and a second insulating tape may include a base layer, and a second coating layer disposed on the base layer, where the recognition pattern is defined in the second coating layer.

In an embodiment, an opening overlapping the recognition pattern may be defined in the conductive layer and the first coating layer.

In an embodiment, an opening overlapping the recognition pattern may be defined in the first coating layer.

A manufacturing method of a display device according to an embodiment of the disclosure includes preparing a display panel including a first area, a second area on which a driving IC is disposed, and a bending area between the first area and the second area, and providing an IC cover layer on the driving IC, in which the providing of the IC cover layer includes providing a first base layer on the second area, providing a first coating layer on the first base layer, providing a conductive tape, in which a first opening is defined, on the first coating layer, providing a second insulating tape, in which a second opening overlapping the first opening is defined, on the conductive tape, and forming a recognition pattern, which overlaps the first opening and the second opening, in the first coating layer.

In an embodiment, the forming the recognition pattern may include providing a laser beam to the first coating layer through the first opening and the second opening.

In an embodiment, when viewed on a plane, each of the first opening and the second opening may have a larger area than the recognition pattern of the first coating layer.

In an embodiment, the recognition pattern may include a QR pattern.

According to an embodiment of the disclosure, an electronic device includes a display panel including a first area, a second area, and a bending area between the first area and the second area, a driving integrated circuit (IC) disposed on the second area, and an IC cover layer disposed on the driving IC, in which the IC cover layer includes a first insulating tape, a second insulating tape disposed on the first insulating tape, and a conductive tape disposed between the first insulating tape and the second insulating tape, and a recognition pattern is defined in one of the first insulating tape and the second insulating tape.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of a display device according to an embodiment of the disclosure.

FIGS. 2 and 3 are views illustrating the folding state of the display device illustrated in FIG. 1.

FIG. 4 is a plan view of a display panel.

FIG. 5 is a cross-sectional view taken along line I-I′ illustrated in FIG. 4.

FIG. 6 is a schematic cross-sectional view of an electronic panel illustrated in FIG. 5.

FIG. 7 is a view illustrating a cross section of the display device corresponding to one pixel illustrated in FIG. 4.

FIG. 8 is a perspective view of a support plate illustrated in FIG. 5.

FIG. 9 is an enlarged view of a first area A1 illustrated in FIG. 8.

FIG. 10 is a cross-sectional view taken along line II-II′ illustrated in FIG. 4.

FIG. 11 is a view illustrating a state in which a bending area illustrated in FIG. 10 is bent.

FIG. 12 is an enlarged view of an IC cover layer illustrated in FIG. 4.

FIG. 13 is an exploded perspective view of the IC cover layer illustrated in FIG. 12.

FIG. 14 is a cross-sectional view taken along line III-III′ illustrated in FIG. 12.

FIG. 15 is a cross-sectional view taken along line III-III′ illustrated in FIG. 12 according to an embodiment of the disclosure.

FIG. 16 is a cross-sectional view taken along line III-III′ illustrated in FIG. 12 according to an embodiment of the disclosure.

FIG. 17 is a cross-sectional view taken along line III-III′ illustrated in FIG. 12 according to an embodiment of the disclosure.

FIGS. 18A to 18F are views illustrating a manufacturing method of the display device according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In this specification, when a first component (or an area, a layer, a portion, etc.) is referred to as being “connected to,” or “coupled to” a second component, it means that the first component may be directly disposed/connected/coupled to the second component, or that a third component may be disposed therebetween.

Like reference numerals refer to like elements. Additionally, in the drawings, the thickness, proportions, and dimensions of components are exaggerated for effective description of technical content.

“The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

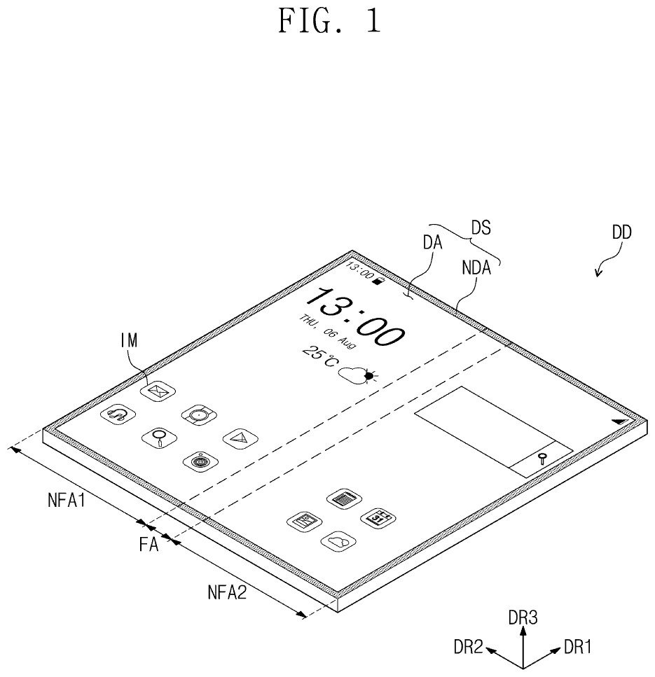

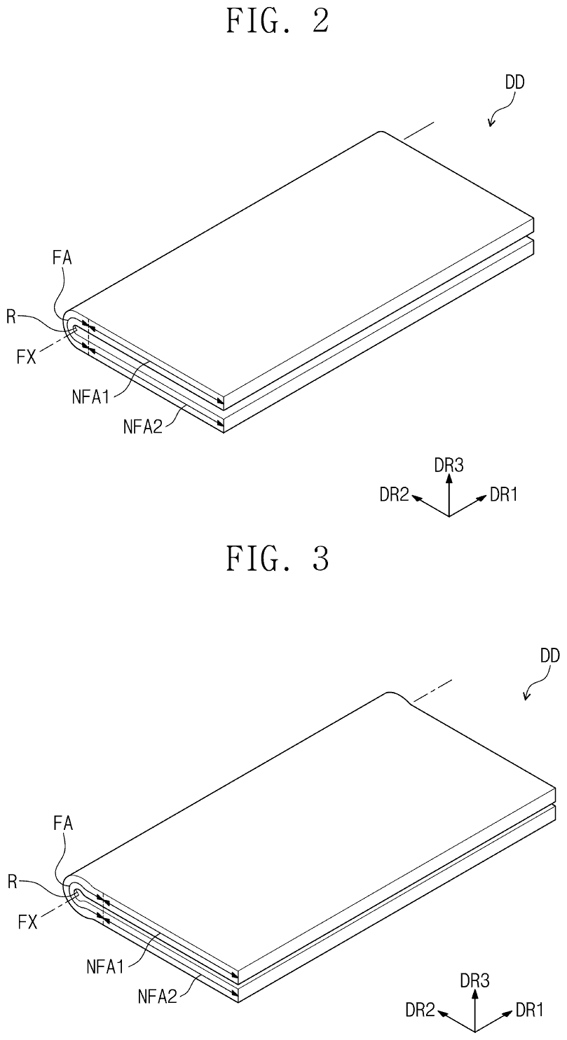

FIG. 1 is a perspective view of a display device according to an embodiment of the disclosure. FIGS. 2 and 3 are views illustrating the folding state of the display device illustrated in FIG. 1.

Referring to FIG. 1, a display device DD according to an embodiment of the disclosure may have a rectangular shape with long sides extending in a first direction DR1 and short sides extending in a second direction DR2 that intersects the first direction DR1 when viewed in a plan view. However, the display device DD is not limited thereto, but may have various shapes, such as a circular shape and a polygonal shape. The display device DD may be a flexible display device.

Herein, a direction that intersects substantially perpendicularly a plane defined by the first direction DR1 and the second direction DR2 is defined as a third direction DR3. Herein, the third direction DR3 may be a thickness direction of the display device DD. In addition, in the disclosure, “when viewed on a plane” or “when viewed in a plan view” may be defined as a state viewed in the third direction DR3.

The display device DD may include a folding area FA and a plurality of non-folding areas NFA1 and NFA2 adjacent to the folding area FA. The non-folding areas NFA1 and NFA2 may include the first non-folding area NFA1 and the second non-folding area NFA2. The folding area FA may be disposed between the first non-folding area NFA1 and the second non-folding area NFA2. The first non-folding area NFA1, the folding area FA, and the second non-folding area NFA2 may be arranged in the second direction DR2.

In an embodiment, for example, the display device DD may include a single folding area FA and two non-folding areas NFA1 and NFA2 as illustrated in FIG. 1, but the number of the folding area FA and the non-folding areas NFA1 and NFA2 is not limited thereto. In an embodiment, for example, the display device DD may include a plurality of non-folding areas more than two and a plurality of folding areas disposed between the non-folding areas.

The upper surface of the display device DD may be defined as a display surface DS, and the display surface DS may be on a plane defined by the first direction DR1 and the second direction DR2. Images IM generated by the display device DD may be provided to a user through the display surface DS.

The display surface DS may include a display area DA and a non-display area NDA around the display area DA. The display area DA may display an image, and the non-display area NDA may not display an image. The non-display area NDA may surround the display area DA and may define an edge area of the display device DD that is printed in a predetermined color.

Referring to FIGS. 2 and 3, the display device DD may be the foldable display device DD that is folded or unfolded. In an embodiment, for example, the folding area FA is bent based on a folding axis FX parallel to the first direction DR1, so the display device DD may be folded. The folding axis FX may be defined as a long axis parallel to the long side of the display device DD. The folding area FA may be bent to have a radius of curvature R.

When the display device DD is folded, the first non-folding area NFA1 and the second non-folding area NFA2 face each other, and the display device DD may be in-folded such that the display surface DS is not exposed to the outside. However, embodiments of the invention are not limited thereto. In an embodiment, for example, the display device DD may be out-folded such that the display surface DS is exposed to the outside about the folding axis FX.

In an embodiment, as illustrated in FIG. 2, a distance between the first non-folding area NFA1 and the second non-folding area NFA2 may be substantially equal to twice the radius of curvature R of the folding area FA. However, the distance between the first non-folding area NFA1 and the second non-folding area NFA2 is not limited thereto, but may be smaller than twice the radius of curvature R as illustrated in FIG. 3.

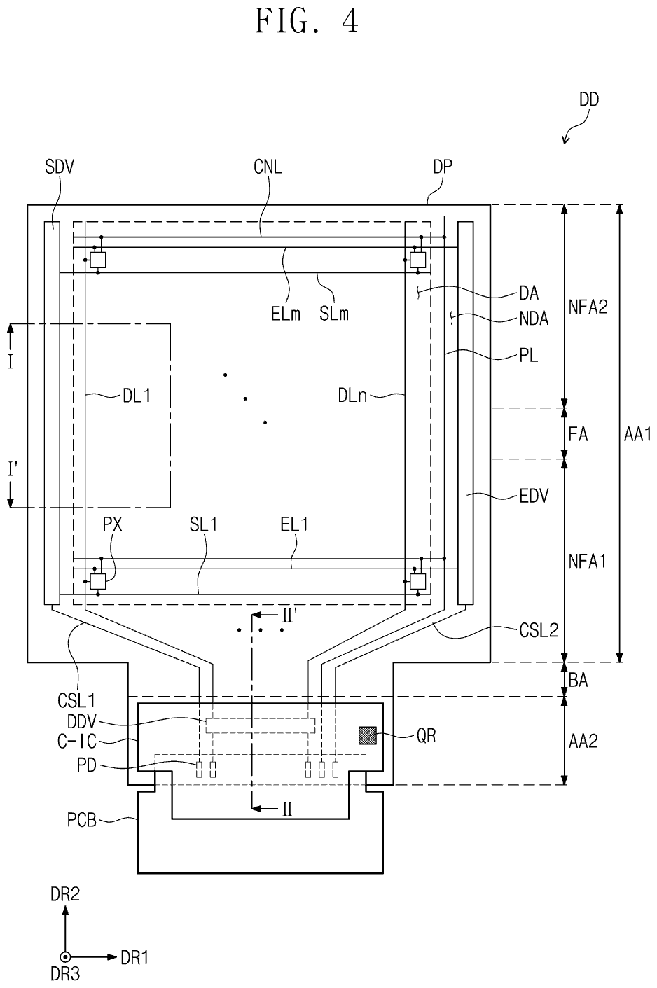

FIG. 4 is a plan view of a display panel included in the display device illustrated in FIG. 1.

Referring to FIG. 4, an embodiment of the display device DD may include a display panel DP, a scan driver SDV, a data driver DDV, an emission driver EDV, a printed circuit board PCB, and an integrated circuit (IC) cover layer C-IC.

In FIG. 4, portions of the data driver DDV and the printed circuit board PCB under the IC cover layer C-IC are illustrated with dotted lines. In addition, the portion of the data driver DDV that overlaps the printed circuit board PCB is also illustrated with a dotted line.

The display panel DP may include a first area AA1, a second area AA2, and a bending area BA between the first area AA1 and the second area AA2. The bending area BA may extend in the first direction DR1, and the first area AA1, the bending area BA, and the second area AA2 may be arranged in the second direction DR2.

The first area AA1 may include the display area DA and the non-display area NDA around the display area DA. The non-display area NDA may surround the display area DA. The display area DA may be an area that displays an image, and the non-display area NDA may be an area that does not display an image. The second area AA2 and the bending area BA may be areas that do not display images.

In an embodiment, as shown in FIG. 4, the first area AA1 may include the first non-folding area NFA1, the second non-folding area NFA2, and the folding area FA between the first non-folding area NFA1 and the second non-folding area NFA2.

The first non-folding area NFA1, the second non-folding area NFA2, and the folding area FA may correspond to the first non-folding area NFA1, the second non-folding area NFA2, and the folding area FA of the display device DD illustrated in FIG. 1.

The first area AA1 may be bent and folded based on the folding axis FX described above. In an embodiment, for example, as the folding area FA of the first area AA1 is folded based on the folding axis FX described above, the display panel DP may be folded.

The display panel DP may include a plurality of pixels PX, a plurality of scan lines SL1 to SLm, a plurality of data lines DL1 to DLn, a plurality of emission lines EL1 to ELm, a first control line CSL1, a second control line CSL2, a power line PL, a plurality of connection lines CNL, and a plurality of pads PD. Here, ‘m’ and ‘n’ are natural numbers. The pixels PX may be disposed in the display area DA and may be connected to the scan lines SL1 to SLm, the data lines DL1 to DLn, and the emission lines EL1 to ELm.

The scan driver SDV and the emission driver EDV may be disposed in the non-display area NDA. The scan driver SDV and the emission driver EDV may be disposed in the non-display area NDA adjacent to each of the opposite sides of the first area AA1 opposite to each other in the first direction DR1. The data driver DDV may be disposed in the second area AA2. The data driver DDV may be manufactured in the form of an IC chip and may be mounted on the second area AA2. The data driver DDV may be defined as a driving IC.

Although not shown, the bending area BA may be bent in a way such that the second area AA2 is disposed under the first area AA1. Accordingly, the data driver DDV may be disposed under the second area AA2.

The scan lines SL1 to SLm may extend in the first direction DR1 and be connected to the scan driver SDV. The data lines DL1 to DLn may extend in the second direction DR2 and be connected to the data driver DDV via the bending area BA. The emission lines EL1 to ELm may extend in the first direction DR1 and be connected to the emission driver EDV.

The power line PL may extend in the second direction DR2 and may be disposed in the non-display area NDA. In an embodiment, as shown in FIG. 4, the power line PL may be disposed between the display area DA and the emission driver EDV, but is not limited thereto. In another embodiment, for example, the power line PL may be disposed between the display area DA and the scan driver SDV.

The power line PL may extend to the second area AA2 via the bending area BA. When viewed on a plane, the power line PL may extend toward the lower end of the second area AA2. The power line PL may receive a driving voltage.

The connection lines CNL may extend in the first direction DR1 and may be arranged in the second direction DR2. The connection lines CNL may be connected to the power line PL and the pixels PX. The driving voltage may be applied to the pixels PX through the power line PL and the connection lines CNL, which are connected to each other.

The first control line CSL1 may be connected to the scan driver SDV and may extend toward the lower end of the second area AA2 via the bending area BA. The second control line CSL2 may be connected to the emission driver EDV and may extend toward the lower end of the second area AA2 via the bending area BA. The data driver DDV may be disposed between the first control line CSL1 and the second control line CSL2.

When viewed on a plane, the pads PD may be disposed to be adjacent to the lower end of the second area AA2. The data driver DDV, the power line PL, the first control line CSL1, and the second control line CSL2 may be connected to the pads PD.

The data lines DL1 to DLn may be connected to the corresponding pads PD through the data driver DDV. In an embodiment, for example, the data lines DL1 to DLn may be connected to the data driver DDV, and the data driver DDV may be connected to the pads PD corresponding to the data lines DL1 to DLn, respectively.

The printed circuit board PCB may be connected to the pads PD disposed in the second area AA2. The printed circuit board PCB may be connected to the display panel DP through the pads PD.

Although not shown, the display device DD may further include a timing controller for controlling the operations of the scan driver SDV, the data driver DDV, and the emission driver EDV, and a voltage generator for generating a driving voltage. The timing controller and the voltage generator may be connected to the pads PD through the printed circuit board PCB.

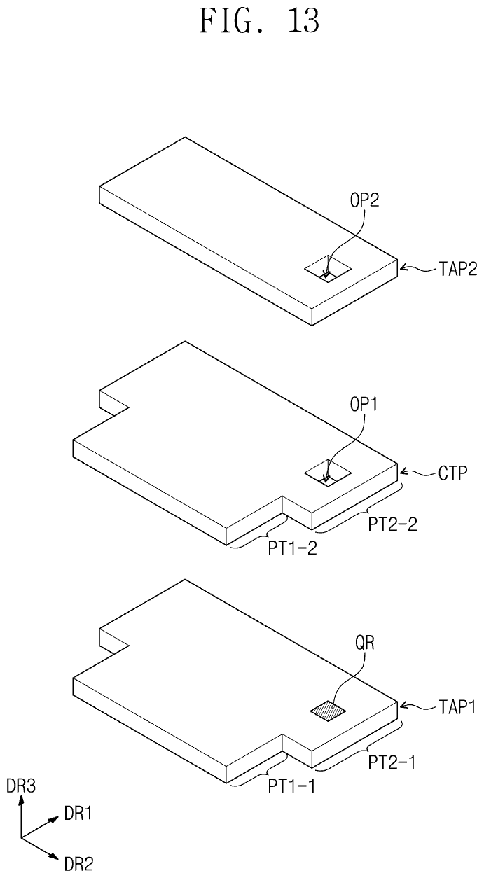

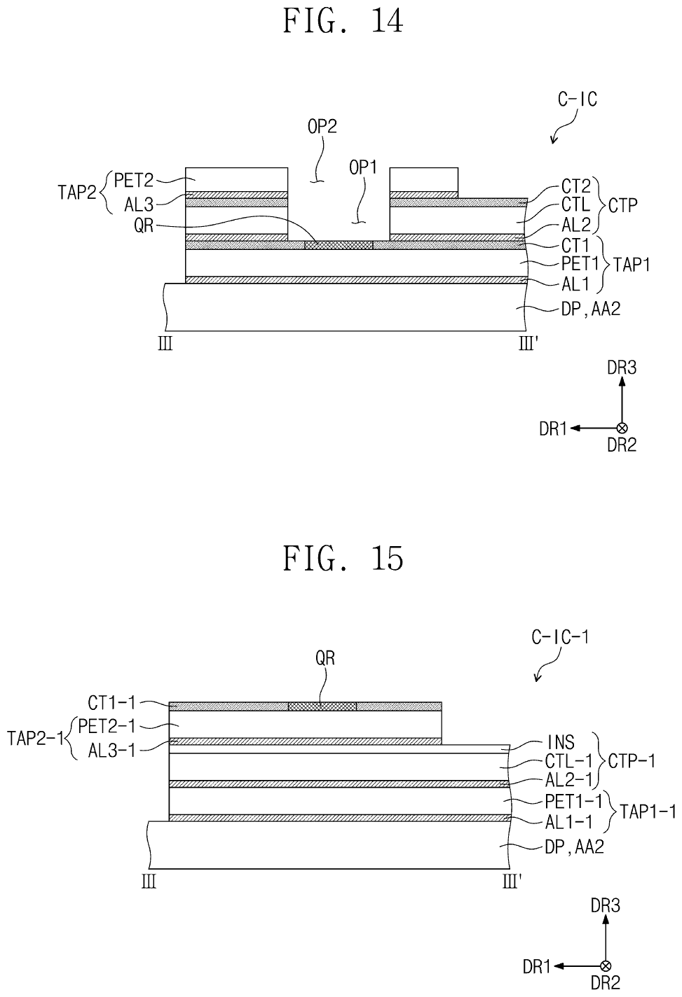

The IC cover layer C-IC may be disposed on the data driver DDV and the printed circuit board PCB. The IC cover layer C-IC may be disposed on the second area AA2. The stacked structure of the IC cover layer C-IC, the data driver DDV, and the printed circuit board PCB is illustrated in FIG. 13 and will be described later in greater detail. A recognition pattern QR may be defined in the IC cover layer C-IC. The specific configuration of the recognition pattern QR will be described with reference to FIGS. 13 and 14 below.

The scan driver SDV generates a plurality of scan signals, and the scan signals may be applied to the pixels PX through the scan lines SL1 to SLm. The data driver DDV generates a plurality of data voltages, and the data voltages may be applied to the pixels PX through the data lines DL1 to DLn. The emission driver EDV generates a plurality of emission signals, and the emission signals may be applied to the pixels PX through the emission lines EL1 to ELm.

The pixels PX may receive the data voltages in response to the scan signals. The pixels PX may display an image by emitting light with a luminance corresponding to the data voltages in response to the emission signals.

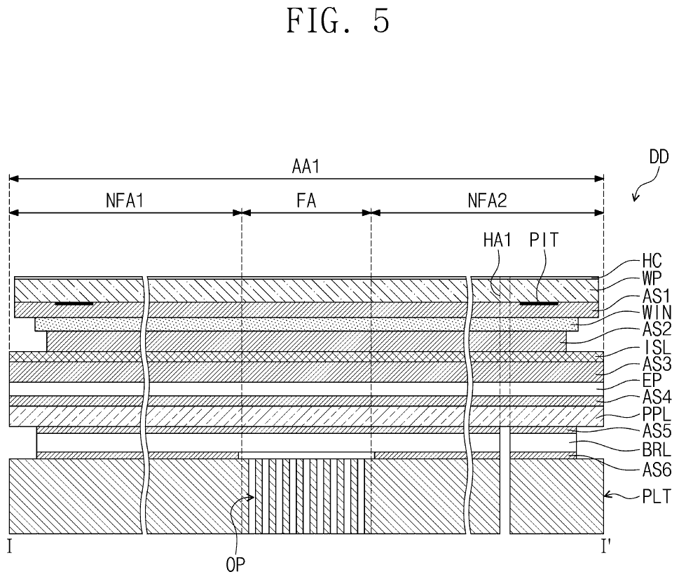

FIG. 5 is a cross-sectional view taken along line I-I′ illustrated in FIG. 4.

Particularly, FIG. 5 illustrates the cross section of the display device DD corresponding to line I-I′.

In an embodiment, the display device DD may be a flexible display module. The display device DD may include the first non-folding area NFA1, the folding area FA, and the second non-folding area NFA2.

In an embodiment, the display device DD may include a window WIN, a window protection layer WP, a hard coating layer HC, a printed layer PIT, an electronic panel EP, an impact absorbing layer ISL, a panel protection layer PPL, a barrier layer BRL, first to sixth adhesive surfaces AS1 to AS6, and a support plate PLT. The impact absorbing layer ISL may be disposed on the electronic panel EP. The impact absorbing layer ISL may protect the electronic panel EP by absorbing external impact applied toward the electronic panel EP from above the display device DD. The impact absorbing layer ISL may be manufactured in the form of a stretched film.

The impact absorbing layer ISL may include a flexible plastic material. The flexible plastic material may be defined as a synthetic resin film. In an embodiment, for example, the impact absorbing layer ISL may include a flexible plastic material such as polyimide (PI) or polyethylene terephthalate (PET).

The window WIN may be disposed on the impact absorbing layer ISL. The window WIN may protect the electronic panel EP from external scratches. The window WIN may have optically transparent properties. In an embodiment, the window WIN may include glass. However, the window WIN is not limited thereto, and may include a synthetic resin film.

The window WIN may have a multi-layer structure or a single-layer structure. In an embodiment, for example, the window WIN may include a plurality of synthetic resin films bonded to each other by an adhesive, or may include a glass substrate and a synthetic resin film bonded to each other by an adhesive.

The window protection layer WP may be disposed on the window WIN. The window protection layer WP may include a flexible plastic material such as polyimide or polyethylene terephthalate. The hard coating layer HC may be disposed on the upper surface of the window protection layer WP.

The printed layer PIT may be disposed on the lower surface of the window protection layer WP. The printed layer PIT may have a black color, but the color of the printed layer PIT is not limited thereto. The printed layer PIT may be adjacent to the edge of the window protection layer WP.

The panel protection layer PPL may be disposed under the display panel DP. The panel protection layer PPL may protect the lower part of the display panel DP. The panel protection layer PPL may include a flexible plastic material. In an embodiment, for example, the panel protection layer PPL may include polyethylene terephthalate (PET).

The barrier layer BRL may be disposed under the panel protection layer PPL. The barrier layer BRL may increase resistance to compressive force due to external pressing. The barrier layer BRL may function to prevent deformation of the electronic panel EP. The barrier layer BRL may include a flexible plastic material such as polyimide or polyethylene terephthalate.

The barrier layer BRL may have a color to absorb light. In an embodiment, for example, the barrier layer BRL may have a black color. In such an embodiment, when the display device DD is viewed from above the display device DD, components disposed under the barrier layer BRL may not be visible.

A first adhesive surface AS1 may be disposed between the window protection layer WP and the window WIN. The window protection layer WP and the window WIN may be bonded to each other by the first adhesive surface AS1. The first adhesive surface AS1 may cover the printed layer PIT.

A second adhesive surface AS2 may be disposed between the window WIN and the impact absorbing layer ISL. The window WIN and the impact absorbing layer ISL may be bonded to each other by the second adhesive surface AS2.

A third adhesive surface AS3 may be disposed between the impact absorbing layer ISL and the electronic panel EP. The impact absorbing layer ISL and the electronic panel EP may be bonded to each other by the third adhesive surface AS3.

A fourth adhesive surface AS4 may be disposed between the electronic panel EP and the panel protection layer PPL. The electronic panel EP and the panel protection layer PPL may be bonded to each other by the fourth adhesive surface AS4.

The fifth adhesive surface AS5 may be disposed between the panel protection layer PPL and the barrier layer BRL. The panel protection layer PPL and the barrier layer BRL may be bonded to each other by the fifth adhesive surface AS5.

The sixth adhesive surface AS6 may be disposed between the barrier layer BRL and the support plate PLT. The barrier layer BRL and the support plate PLT are bonded to each other by the sixth adhesive surface AS6.

Hereinafter, in the disclosure, “thickness” may refer to a value measured in the third direction DR3, and “width” may refer to a value measured in the first direction DR1 or the second direction DR2, which is a horizontal direction.

The sixth adhesive surface AS6 may overlap the first non-folding area NFA1 and the second non-folding area NFA2, and may not overlap the folding area FA. That is, the sixth adhesive surface AS6 may be open in the folding area FA.

The first to sixth adhesive surfaces AS1 to AS6 may include transparent adhesives such as a pressure sensitive adhesive (PSA) or an optically clear adhesive (OCA), but the type of an adhesive is not limited thereto.

The thickness of the panel protection layer PPL may be smaller than the thickness of the window protection layer WP, and the thickness of the barrier layer BRL may be smaller than the thickness of the panel protection layer PPL. The thickness of the electronic panel EP may be smaller than the thickness of the barrier layer BRL and may be equal to the thickness of the window WIN. The thickness of the impact absorbing layer ISL may be smaller than the thickness of the electronic panel EP.

The thickness of the first adhesive surface AS1 may be equal to the thickness of the barrier layer BRL, and the thickness of each of the second adhesive surface AS2 and the third adhesive surface AS3 may be equal to the thickness of the panel protection layer PPL. The thickness of the fourth adhesive surface AS4 may be equal to the thickness of the fifth adhesive surface AS5.

The thickness of each of the fourth adhesive surface AS4 and the fifth adhesive surface AS5 may be smaller than the thickness of the electronic panel EP and may be larger than the thickness of the impact absorbing layer ISL. The thickness of the sixth adhesive surface AS6 may be smaller than the thickness of the impact absorbing layer ISL. The thickness of the hard coating layer HC may be smaller than the thickness of the sixth adhesive surface AS6.

The electronic panel EP, the impact absorbing layer ISL, the panel protection layer PPL, and the third and fourth adhesive surfaces AS3 and AS4 may have a same width as each other. The window protection layer WP and the first adhesive surface AS1 may have a same width as each other. The barrier layer BRL and the fifth and sixth adhesive surfaces AS5 and AS6 may have a same width as each other.

The widths of the electronic panel EP, the impact absorbing layer ISL, the panel protection layer PPL, and the third and fourth adhesive surfaces AS3 and AS4 may be larger than the widths of the window protection layer WP and the first adhesive surface AS1. The edges of the electronic panel EP, the impact absorbing layer ISL, the panel protection layer PPL, and the third and fourth adhesive surfaces AS3 and AS4 may be disposed at a side outer than the edges of the window protection layer WP and the first adhesive surface AS1.

The widths of the window WIN and the second adhesive surface AS2 may be smaller than the widths of the window protection layer WP and the first adhesive surface AS1. The width of the second adhesive surface AS2 may be smaller than the width of the window WIN. The edge of the window WIN may be disposed at a side inner than the edges of the window protection layer WP and the first adhesive surface AS1. The edge of the second adhesive surface AS2 may be disposed at a side inner than the edge of the window WIN.

The widths of the barrier layer BRL and the fifth and sixth adhesive surfaces AS5 and AS6 may be smaller than the widths of the window protection layer WP and the first adhesive surface AS1. The edges of the barrier layer BRL and the fifth and sixth adhesive surfaces AS5 and AS6 may be placed at a side inner than the edges of the window protection layer WP and the first adhesive surface AS1.

The support plate PLT may be disposed under the electronic panel EP and support the electronic panel EP. The support plate PLT may be disposed under the barrier layer BRL.

The support plate PLT may be more rigid than a display part. The support plate PLT may include a non-metallic material. In an embodiment, for example, the support plate PLT may include a reinforced fiber composite. The reinforced fiber composite may be carbon fiber reinforced plastic (CFRP) or glass fiber reinforced plastic (GFRP).

The support plate PLT may be made lighter by including a reinforcing fiber composite. In an embodiment, the support plate PLT includes a reinforced fiber composite material, such that the support plate PLT has a weight lighter than a metal support plate including or made of a metal material and has a similar level of modulus and strength to that of the metal support plate.

Since the support plate PLT includes a reinforced fiber composite, the shape processing of the support plate PLT may be easier than that of a metal support plate. In an embodiment, for example, the support plate PLT including a reinforced fiber composite may be more easily processed through a laser process or a micro-blasting process.

A plurality of openings OP may be defined in portions of the support plate PLT that overlaps the folding area FA. The openings OP may be formed by removing the portions of the support plate PLT in the third direction DR3. The openings OP may be formed through the laser process or the micro-blasting process described above.

The openings OP are defined in the portion of the support plate PLT that overlaps the folding area FA, and thus the flexibility of the portion of the support plate PLT that overlaps the folding area FA may be increased. As a result, the support plate PLT may be easily folded based on the folding area FA. A shape of the openings OP will be described in detail below.

The width of the support plate PLT may be substantially the same as the width of the electronic panel EP.

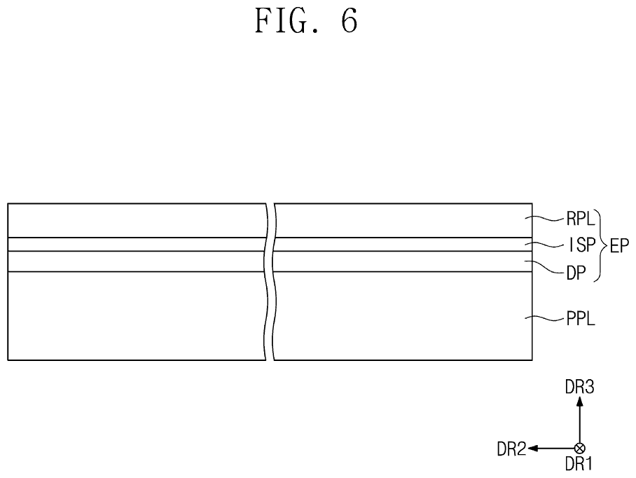

FIG. 6 is a schematic cross-sectional view of an electronic panel illustrated in FIG. 5.

In FIG. 6, the panel protection layer PPL disposed under the electronic panel EP is illustrated together with the electronic panel EP.

Referring to FIG. 6, in an embodiment, the electronic panel EP may include the display panel DP, an input sensing part ISP disposed on the display panel DP, and a reflection prevention layer RPL disposed on the input sensing part ISP. The display panel DP may be a flexible display panel. In an embodiment, for example, the display panel DP may include a flexible substrate and a plurality of elements disposed on the flexible substrate.

The display panel DP according to an embodiment of the disclosure may be a light emitting display panel, and is not particularly limited thereto. In an embodiment, for example, the display panel DP may be an organic light emitting display panel or an inorganic light emitting display panel. The light emitting layer of the organic light emitting display panel may include an organic light emitting material. The light emitting layer of the inorganic light emitting display panel may include quantum dots and quantum rods, etc. Hereinafter, for convenience of description, embodiments where the display panel DP is the organic light emitting display panel will be described in detail, but not being limited thereto.

The input sensing part ISP may include a plurality of sensor parts (not shown) to sense external input in a capacitive manner. In an embodiment, the input sensing part ISP may be formed directly on the display panel DP when manufacturing a display module DM.

The reflection prevention layer RPL may be disposed on the input sensing part ISP. The reflection prevention layer RPL may be formed directly on the input sensing part ISP when manufacturing a display module. The reflection prevention layer RPL may be defined as an external light reflection prevention film. The reflection prevention layer RPL may reduce the reflectance of external light incident from above the display device DD toward the display panel DP.

In an embodiment, for example, the input sensing part ISP may be formed directly on the display panel DP, and the reflection prevention layer RPL may be formed directly on the input sensing part ISP, but the embodiments of the disclosure are not limited thereto. In another embodiment, for example, the input sensing part ISP may be manufactured separately and attached to the display panel DP by an adhesive layer, and the reflection prevention layer RPL may be manufactured separately and attached to the input sensing part ISP by an adhesive layer.

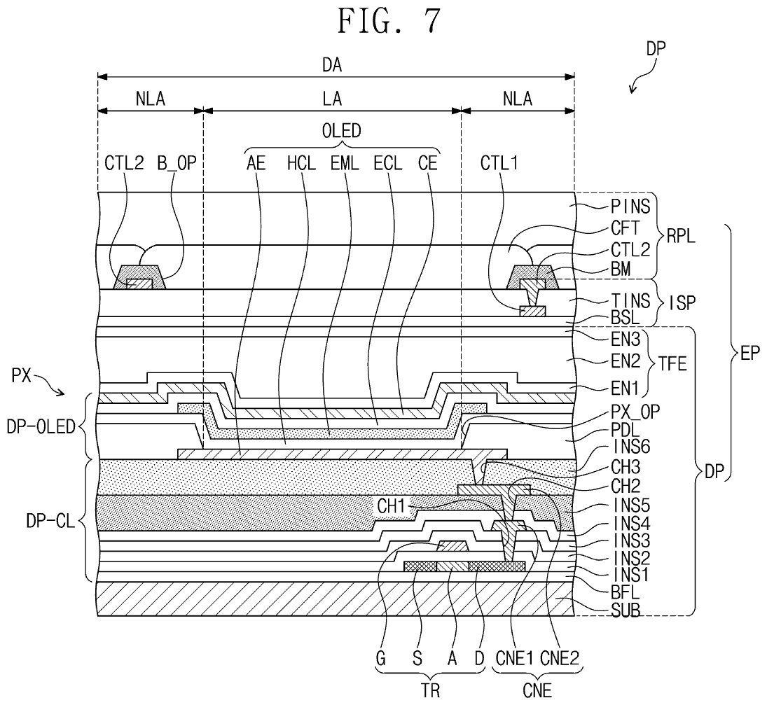

FIG. 7 is a view illustrating a cross section of the display device corresponding to one pixel illustrated in FIG. 4.

Referring to FIG. 7, in an embodiment, the pixel PX may include a transistor TR and a light emitting element OLED. The light emitting element OLED may include a first electrode AE (or an anode), a second electrode CE (or a cathode), a hole control layer HCL, an electronic control layer ECL, and an emission layer EML.

The transistor TR and the light emitting element OLED may be disposed on a substrate SUB. Although only one transistor TR is illustrated in FIG. 7 as an example, the pixel PX may include a plurality of transistors and at least one capacitor for driving the light emitting element OLED.

The display area DA may include an emission area LA corresponding to each of the pixels PX and a non-emission area NLA around the emission area LA. The light emitting element OLED may be disposed in the emission area LA.

A buffer layer BFL may be disposed on the substrate SUB and may be an inorganic layer. A semiconductor pattern may be disposed on the buffer layer BFL. The semiconductor pattern may include polysilicon, amorphous silicon, or metal oxide.

The semiconductor pattern may be doped with an N-type dopant or a P-type dopant. The semiconductor pattern may include a high doping area and a low doping area. The high doping area is greater in conductivity than the low doping area, and may substantially serve as the source electrode and the drain electrode of the transistor TR. The low doping area may substantially correspond to the active (or channel) of the transistor.

A source S, an active A, and a drain D of the transistor TR may be formed from (or defined by portions of) the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR and the light emitting element OLED to each other. The first connection electrode CNE1 may be disposed on the third insulating layer INS3 and may be connected to the drain D through a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 defined in the fourth and fifth insulating layers INS4 and INS5.

A sixth insulating layer INS6 may be disposed on the second connection electrode CNE2. A layer between the buffer layer BFL and the sixth insulating layer INS6 may be defined as a circuit element layer DP-CL. The first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through a contact hole CH3 defined in the sixth insulating layer INS6. A pixel definition film PDL having an opening PX_OP defined to expose a predetermined portion of the first electrode AE may be disposed on the first electrode AE and the sixth insulating layer INS6.

The hole control layer HCL may be disposed on the first electrode AE and the pixel definition film PDL. The hole control layer HCL may include a hole transport layer and a hole injection layer.

The emission layer EML may be disposed on the hole control layer HCL. The emission layer EML may be disposed in an area corresponding to the opening PX_OP. The emission layer EML may include an organic material and/or an inorganic material. In an embodiment, for example, the emission layer EML may generate one of red, green, and blue light.

The electronic control layer ECL may be disposed on the emission layer EML and the hole control layer HCL. The electronic control layer ECL may include an electron transport layer and an electron injection layer. The hole control layer HCL and the electronic control layer ECL may be commonly disposed in the emission area LA and the non-emission area NLA.

The second electrode CE may be disposed on the electronic control layer ECL. The second electrode CE may be commonly disposed in the pixels PX. A layer in which the light emitting element OLED is disposed may be defined as a display element layer DP-OLED.

A thin film encapsulation layer TFE may be disposed on the second electrode CE and cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first encapsulation layer EN1 and the third encapsulation layer EN3 may include an inorganic insulating layer and may protect the pixel PX from moisture/oxygen. The second encapsulation layer EN2 may include an organic insulating layer and may protect the pixel PX from foreign substances such as dust particles.

A first voltage may be applied to the first electrode AE through the transistor TR, and a second voltage having a level lower than the first voltage may be applied to the second electrode CE. Holes and electrons injected into the emission layer EML combine to form excitons, and as the excitons transition to the ground state, the light emitting element OLED may emit light.

The input sensing part ISP may be disposed on the thin film encapsulation layer TFE. In an embodiment, for example, the input sensing part ISP may be manufactured directly on the upper surface of the thin film encapsulation layer TFE.

A base layer BSL may be disposed on the thin film encapsulation layer TFE. The base layer BSL may include an inorganic insulating layer. At least one inorganic insulating layer as the base layer BSL may be provided on the thin film encapsulation layer TFE.

The input sensing part ISP may include a first conduction pattern CTL1 and a second conduction pattern CTL2 disposed on the first conduction pattern CTL1. The first conduction pattern CTL1 may be disposed on the base layer BSL. An insulating layer TINS may be disposed on the base layer BSL to cover the first conduction pattern CTL1. The insulating layer TINS may include an inorganic insulating layer or an organic insulating layer. The second conduction pattern CTL2 may be disposed on the insulating layer TINS.

The first and second conduction patterns CTL1 and CTL2 may overlap the non-emission area NLA. Although not shown, the first and second conduction patterns CTL1 and CTL2 may be disposed on the non-emission area NLA between emission areas PA and may have a mesh shape.

The first and second conduction patterns CTL1 and CTL2 may form the sensors of the input sensing part ISP described above. In an embodiment, for example, the first and second conduction patterns CTL1 and CTL2 in a mesh shape may be separated from each other in a predetermined area to form the sensors. A portion of the second conduction pattern CTL2 may be connected to the first conduction pattern CTL1.

The reflection prevention layer RPL may be disposed on the second conduction pattern CTL2. The reflection prevention layer RPL may include a black matrix BM and a plurality of color filters CFT. The black matrix BM may overlap the non-emission area NLA, and the color filters CFT may overlap the emission areas PA, respectively.

The black matrix BM may be disposed on the insulating layer TINS to cover the second conduction pattern CTL2. An opening B_OP overlapping with the emission area LA and the opening PX_OP may be defined in the black matrix BM. The black matrix BM may absorb and block light. The width of the opening B_OP may be larger than the width of the opening PX_OP.

The color filters CFT may be disposed on the insulating layer TINS and the black matrix BM. The color filters CFT may be disposed in the openings B_OP, respectively. A planarization insulating layer PINS may be disposed on the color filters CFT. The planarization insulating layer PINS may provide a flat upper surface.

When external light traveling toward the display panel DP is reflected from the display panel DP and provided back to an external user, the user may perceive the external light like a mirror. To prevent this phenomenon, for example, the reflection prevention layer RPL may include the plurality of color filters CFT that display same color as the pixels PX of the display panel DP. The color filters CFT may filter external light into the same colors as the pixels PX. In this case, the external light may not be visible to a user.

However, embodiments of the disclosure are not limited thereto, and the reflection prevention layer RPL may include a polarizing film to reduce reflectance of external light. In an embodiment, the polarizing film may be manufactured separately and attached to the input sensing part ISP by an adhesive layer. The polarizing film may include a retarder and/or a polarizer.

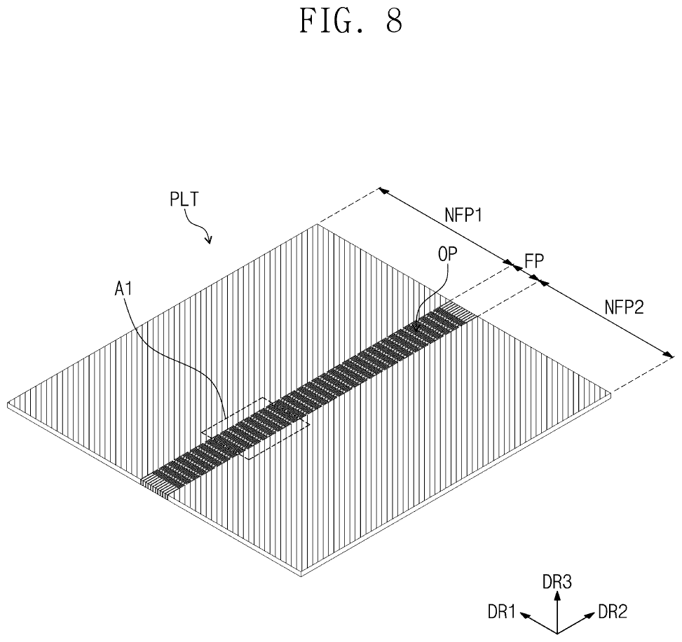

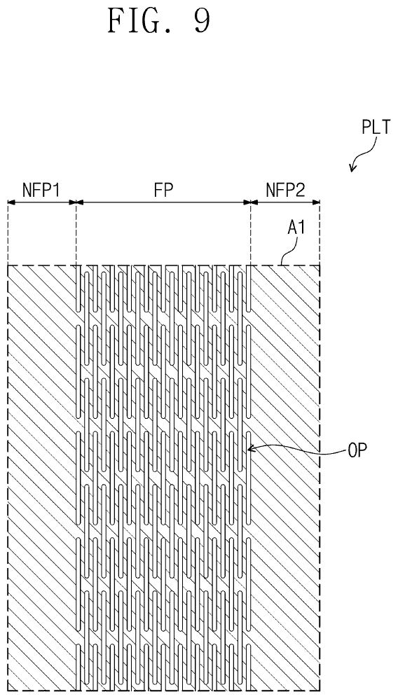

FIG. 8 is a perspective view of a support plate illustrated in FIG. 5. FIG. 9 is an enlarged view of a first area A1 illustrated in FIG. 8.

Referring to FIGS. 8 and 9, in an embodiment, the plurality of openings OP may be defined as a grid pattern in the folding area FA of the support plate. The openings OP may be arranged according to a predetermined rule. Since the openings OP are defined in the folding area FA, the area of the folding area FA may be reduced and the rigidity of the folding area FA may be decreased. In such an embodiment where the openings OP are defined in the folding area FA, the flexibility of the folding area FA may be increased compared to a case where the openings OP are not defined in the folding area FA. Accordingly, in such an embodiment, the folding area FA may be bent more easily.

Referring to FIG. 9, the openings OP may be arranged in the first direction DR1 and the second direction DR2. The openings OP may extend longer in the second direction DR2 than in the first direction DR1. In an embodiment, for example, an opening OP arranged in an h-th column and an opening OP arranged in an (h+1)-th column may be arranged to be staggered with each other. Here, ‘h’ is a natural number, and the column may correspond to the second direction DR2.

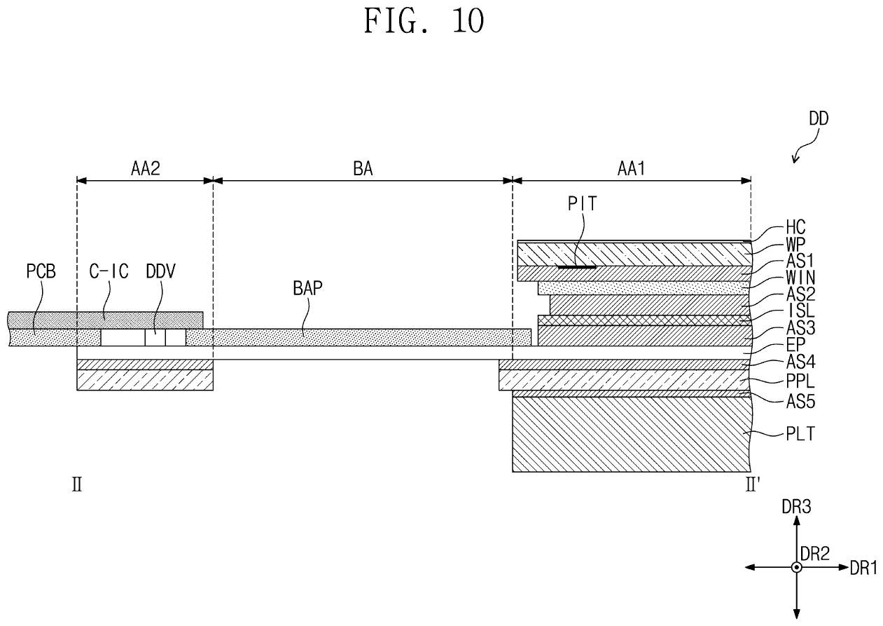

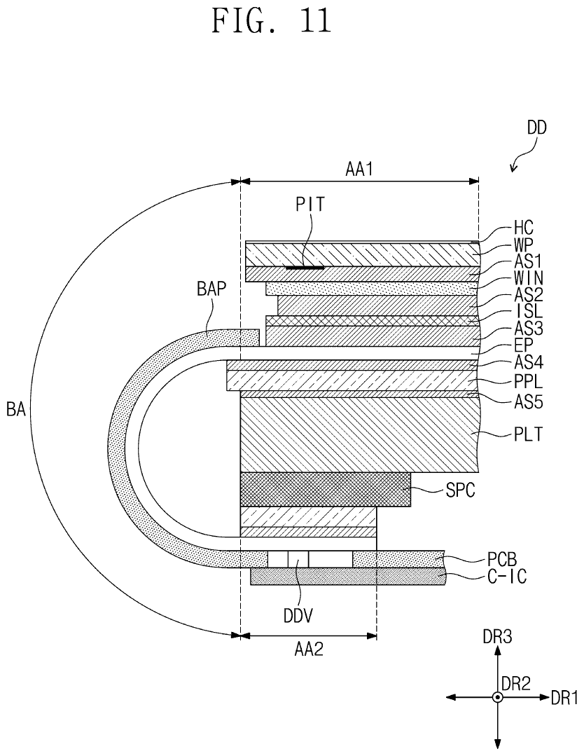

FIG. 10 is a cross-sectional view taken along line II-II′ illustrated in FIG. 4. FIG. 11 is a view illustrating a state in which a bending area illustrated in FIG. 10 is bent.

Referring to FIG. 10, in an embodiment, the panel protection layer PPL and the fourth adhesive surface AS4 may not be disposed under the bending area BA. The panel protection layer PPL and the fourth adhesive surface AS4 may be disposed under the second area AA2 of the electronic panel EP. The data driver DDV may be disposed on the second area AA2 of the electronic panel EP.

The display device DD may further include a bending protection layer BAP. The bending protection layer BAP may be disposed on the bending area BA, a portion of the first area AA1 adjacent to the bending area BA, and a portion of the second area AA2 adjacent to the bending area BA. The bending protection layer BAP may extend continuously from a portion of the first area AA1 adjacent to the bending area BA through the bending area BA to a portion of the second area AA2 adjacent to the bending area BA.

The bending protection layer BAP may be spaced apart from the third adhesive surface AS3. The bending protection layer BAP may be spaced apart from the data driver DDV in the second area AA2. The bending protection layer BAP may include acrylic-based resin or urethane-based resin.

The IC cover layer C-IC may be disposed on the second area AA2. The IC cover layer C-IC may be disposed on the data driver DDV to cover the data driver DDV. The IC cover layer C-IC may include a plurality of insulating tapes and a conductive tape disposed between the insulating tapes, and this configuration will be described in detail below.

The printed circuit board PCB may be disposed on a portion of the second area AA2. The IC cover layer C-IC may be disposed on the printed circuit board PCB. The printed circuit board PCB may be spaced apart from the data driver DDV in the second area AA2. The IC cover layer C-IC may be disposed on portions of the printed circuit board PCB and the bending protection layer BAP.

Referring to FIG. 11, the bending area BA may be bent to have a predetermined curvature. The bending area BA may be bent in a way such the second area AA2 may be disposed under the first area AA1. Accordingly, the data driver DDV may be disposed under the first area AA1.

The display device DD may further include a spacer SPC disposed under the support plate PLT. The spacer SPC may be a double-sided tape. In an embodiment, for example, the spacer SPC may include a base layer such as flexible polyethylene terephthalate and an adhesive disposed on each of the upper and lower surfaces of the base layer.

The panel protection layer PPL disposed on the second area AA2 may be disposed under the spacer SPC. The panel protection layer PPL disposed on the second area AA2 may be attached to the spacer SPC.

The IC cover layer C-IC may be disposed under the second area AA2 to cover the data driver DDV. The IC cover layer C-IC may be disposed under a portion of the bending protection layer BAP and a portion of the printed circuit board PCB disposed under the second area AA2.

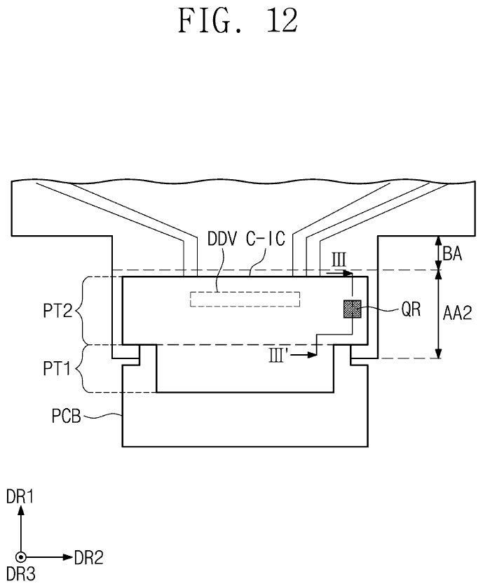

FIG. 12 is a view of an IC cover layer illustrated in FIG. 4.

In FIG. 12, the data driver DDV under the IC cover layer C-IC is illustrated with a dotted line, and the pads PD and wires under the IC cover layer C-IC are omitted for convenience of illustration.

Referring to FIG. 12, in an embodiment, the IC cover layer C-IC may be disposed on the second area AA2 and the printed circuit board PCB. The IC cover layer C-IC may include a first part PT1 and a second part PT2. The second part PT2 may be disposed on the second area AA2. The second part PT2 may cover the data driver DDV. The first part PT1 may extend from the second part PT2 toward the printed circuit board PCB and may be disposed on a portion of the printed circuit board PCB adjacent to the second area AA2. The second part PT2 may have a larger width than the first part PT1 in the second direction DR2.

The recognition pattern QR may be defined in the second part PT2. The recognition pattern QR may include product information and customer information, etc. In an embodiment, for example, the recognition pattern QR may include a quick response (QR) pattern.

When viewed on a plane, the recognition pattern QR may not overlap the data driver DDV. In an embodiment, for example, the recognition pattern QR is defined to be adjacent to one side of the data driver DDV, but the location of the recognition pattern QR is not limited thereto.

The recognition pattern QR may be defined by a laser beam. The recognition pattern QR may be formed by irradiating the IC cover layer C-IC with a laser. The recognition pattern QR may be formed by removing a portion of the IC cover layer C-IC.

FIG. 13 is an exploded perspective view of the IC cover layer illustrated in FIG. 12.

Referring to FIG. 13, an embodiment of the IC cover layer C-IC may include a first insulating tape TAP1, a conductive tape CTP, and a second insulating tape TAP2.

The first insulating tape TAP1 may be disposed on the data driver DDV described above. The conductive tape CTP may be disposed on the first insulating tape TAP1, and the second insulating tape TAP2 may be disposed on the conductive tape CTP. Accordingly, the second insulating tape TAP2 may be disposed on the first insulating tape TAP1, and the conductive tape CTP may be disposed between the first insulating tape TAP1 and the second insulating tape TAP2.

The first insulating tape TAP1 may include a first part PT1-1 and a second part PT2-1. The first part PT1-1 may extend from the second part PT2-1. The first part PT1-1 may have a smaller width than the second part PT2-1 in the second direction DR2.

The conductive tape CTP may include a first part PT1-2 and a second part PT2-2. The first part PT1-2 may extend from the second part PT2-2. The first part PT1-2 may have a smaller width than the second part PT2-2 in the second direction DR2.

When viewed on a plane, the first part PT1-1 and the first part PT1-2 may overlap each other to define the first part PT1 described above. When viewed on a plane, the second part PT2-1, the second part PT2-2, and the second insulating tape TAP2 may overlap each other to define the second part PT2 described above.

The recognition pattern QR may be defined in the first insulating tape TAP1. In an embodiment, for example, the recognition pattern QR is defined in the first insulating tape TAP1, but is not limited thereto. In another embodiment, the recognition pattern QR may be defined in the second insulating tape TAP2, and this configuration will be described with reference to FIGS. 14 to 17 below.

A first opening OP1 may be defined in the conductive tape CTP. When viewed on a plane, the first opening OP1 may overlap the recognition pattern QR.

A second opening OP2 may be defined in the second insulating tape TAP2. When viewed on a plane, the second opening OP2 may overlap the first opening OP1 and the recognition pattern QR. When viewed on a plane, each of the first opening OP1 and the second opening OP2 may have an area larger than the area of the recognition pattern QR.

FIG. 14 is a cross-sectional view taken along line III-III′ illustrated in FIG. 12.

For convenience of illustration and description, for example, in FIG. 14, the printed circuit board PCB is omitted, and the cross section of each of the display panel DP and the IC cover layer C-IC on the display panel DP is illustrated.

Referring to FIGS. 12 and 14, the first insulating tape TAP1 and the conductive tape CTP may extend further outward than the second insulating tape TAP2. Accordingly, portions extending outward than the second insulating tape TAP2 may be the first part PT1-1 of the first insulating tape TAP1 and the first part PT1-2 of the conductive tape CTP illustrated in FIG. 13.

The first insulating tape TAP1 may be disposed on the display panel DP. The first insulating tape TAP1 may include a first adhesive layer AL1, a first base layer PET1, and a first coating layer CT1. The first base layer PET1 may be disposed on the display panel DP. The first base layer PET1 may include an organic insulating layer. The first coating layer CT1 may be disposed on the first base layer PET1.

The recognition pattern QR may be defined in the first coating layer CT1. The first coating layer CT1 may have a black color. The first coating layer CT1 may be matte (or have a matte surface) to minimize light reflection.

The first adhesive layer AL1 may be disposed between the display panel DP and the first base layer PET1. The first base layer PET1 may be attached to the display panel DP by the first adhesive layer AL1.

The conductive tape CTP may be disposed on the first insulating tape TAP1. Edges of the first insulating tape TAP1 and the conductive tape CTP may overlap each other. The first opening OP1 defined in the conductive tape CTP may overlap the recognition pattern QR. Accordingly, the recognition pattern QR may be exposed to the outside through the first opening OP1. Since the first opening OP1 has a larger area than the recognition pattern QR, the recognition pattern QR may be sufficiently exposed to the outside by the first opening OP1.

The conductive tape CTP may include a second adhesive layer AL2, a conductive layer CTL, and a second coating layer CT2. The first opening OP1 may be defined through the second adhesive layer AL2, the conductive layer CTL and the second coating layer CT2. The conductive layer CTL may be disposed on the first coating layer CT1. The second adhesive layer AL2 may be disposed between the first coating layer CT1 and the conductive layer CTL. The conductive layer CTL may be attached to the first coating layer CT1 by the second adhesive layer AL2. The conductive layer CTL may include a conductive material. The conductive layer CTL may protect the data driver DDV by blocking external static electricity that may be applied to the data driver DDV. Although not shown, the conductive layer CTL may be connected to a ground terminal.

The second coating layer CT2 may be disposed on the conductive layer CTL. The second coating layer CT2 may protect the conductive layer CTL. In an embodiment, for example, the second coating layer CT2 may protect the conductive layer CTL from physical corrosion which is damage from an external environment or chemical corrosion caused by oxygen, bases, alkalis, and acids, etc. The second coating layer CT2 may absorb and block light. The second coating layer CT2 may have a color that absorbs light. In an embodiment, for example, the second coating layer CT2 may have a black color.

The second insulating tape TAP2 may be disposed on the conductive tape CTP. One side of the second insulating tape TAP2 may be disposed at a side inner than one side of the first insulating tape TAP1 and one side of the conductive tape CTP. When viewed in the second direction DR2, the second insulating tape TAP2 may be formed to be stepped from the first insulating tape TAP1 and the conductive tape CTP. The second opening OP2 defined in the second insulating tape TAP2 may overlap the recognition pattern QR and the first opening OP1. The area of the second opening OP2 may be defined to be larger than the area of the recognition pattern QR. Accordingly, the recognition pattern QR may be exposed to the outside through the first opening OP1 and the second opening OP2.

Since the recognition pattern QR is exposed through the first opening OP1 and the second opening OP2, the recognition pattern QR may be easily recognized through a device that recognizes the recognition pattern QR. Accordingly, product information of the display device DD may be provided to a user more easily.

The second insulating tape TAP2 may include a third adhesive layer AL3 and a second base layer PET2. The second opening OP2 may be defined in the third adhesive layer AL3 and the second base layer PET2. The second base layer PET2 may be disposed on the second coating layer CT2. The second base layer PET2 may include an organic insulating layer.

The third adhesive layer AL3 may be disposed between the second base layer PET2 and the second coating layer CT2. The second base layer PET2 may be attached to the second coating layer CT2 by the third adhesive layer AL3.

In an embodiment, the first adhesive layer AL1 to the third adhesive layer AL3 may include a pressure sensitive adhesive (PSA), but the type of an adhesive is not limited thereto. In another embodiment, for example, the first adhesive layer AL1 to the third adhesive layer AL3 may include an optically clear adhesive (OCA).

In a case where a coating layer having a black color is disposed on the recognition pattern QR, the recognition pattern QR may not be recognized. In an embodiment of the disclosure, since the second opening OP2 overlapping the recognition pattern QR is defined in the second coating layer CT2 having a black color, the recognition pattern QR may be recognized more easily. In addition, in an embodiment of the disclosure, the portions of the conductive tape CTP and the second insulating tape TAP2 that overlap the recognition pattern QR are removed, and thus no separate structure is disposed on the recognition pattern QR, so the recognition pattern QR may be recognized more easily.

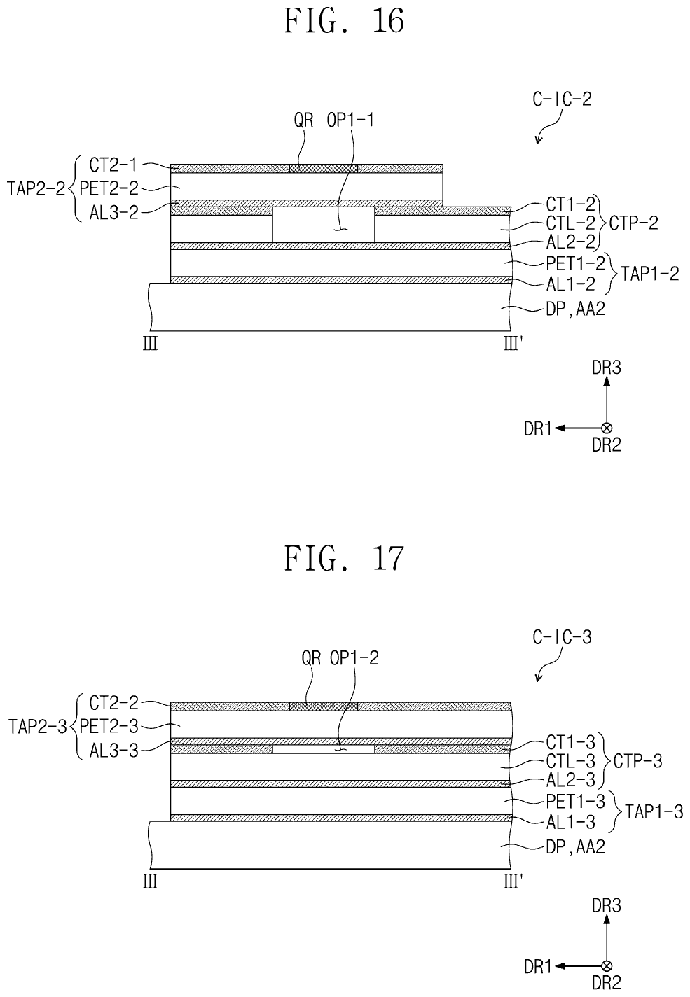

FIG. 15 is a cross-sectional view taken along line III-III′ illustrated in FIG. 12 according to an embodiment of the disclosure.

Hereinafter, a configuration shown in FIG. 15 will be described, focusing on a configuration different from the configuration shown in FIG. 14, and any repetitive detailed description of the same or like elements as those described above will be omitted or simplified.

Referring to FIG. 15, an embodiment of an IC cover layer C-IC-1 may include a first insulating tape TAP1-1, a conductive tape CTP-1, and a second insulating tape TAP2-1.

The first insulating tape TAP1-1 may be disposed on the display panel DP. The first insulating tape TAP1-1 may include a first adhesive layer AL1-1 and a first base layer PET1-1. The first base layer PET1-1 may be disposed on the display panel DP.

The first adhesive layer AL1-1 may be disposed between the display panel DP and the first base layer PET1-1. The first base layer PET1-1 and the display panel DP may be attached to each other by the first adhesive layer AL1-1.

The conductive tape CTP-1 may be disposed on the first insulating tape TAP1-1. The conductive tape CTP-1 may include a second adhesive layer AL2-1, a conductive layer CTL-1, and an insulating layer INS.

The conductive layer CTL-1 may be disposed on the first base layer PET1-1.

The insulating layer INS may be disposed on the conductive layer CTL-1. The insulating layer INS may be transparent.

The second adhesive layer AL2-1 may be disposed between the first base layer PET1-1 and the conductive layer CTL-1. The conductive layer CTL-1 and the first base layer PET1-1 may be attached to each other by the second adhesive layer AL2-1.

The second insulating tape TAP2-1 may be disposed on the conductive tape CTP-1. The second insulating tape TAP2-1 may include a third adhesive layer AL3-1, a second base layer PET2-1, and a first coating layer CT1-1. One side of the second insulating tape TAP2-1 may be disposed at a side inner than one side of the first insulating tape TAP1-1 and one side of the conductive tape CTP-1. When viewed in the second direction DR2, the second insulating tape TAP2-1 may be formed to be stepped from the first insulating tape TAP1-1 and the conductive tape CTP-1.

The second base layer PET2-1 may be disposed on the insulating layer INS. The third adhesive layer AL3-1 may be disposed between the second base layer PET2-1 and the insulating layer INS. The second base layer PET2-1 and the insulating layer INS may be attached to each other by the third adhesive layer AL3-1.

The first coating layer CT1-1 may be disposed on the second base layer PET2-1. The recognition pattern QR may be defined in the first coating layer CT1-1. The first coating layer CT1-1 may have a black color. The first coating layer CT1-1 may be matte to minimize light reflection.

The insulating layer INS may be defined on the conductive layer CTL-1 to protect the upper surface of the conductive layer CTL-1. In an embodiment, for example, since the insulating layer INS covers the upper surface of the conductive layer CTL-1, the corrosion of the upper surface of the conductive layer CTL-1 may be prevented by the insulating layer INS.

Since the insulating layer INS has a transparent color, a layer having a black color may not be disposed under the recognition pattern QR. In a case where a layer having a black color is disposed under the recognition pattern QR including a QR code, the QR code formed in a black pattern may not be effectively recognized. In such an embodiment, the insulating layer INS does not have a black color, such that the recognition pattern QR may be easily recognized.

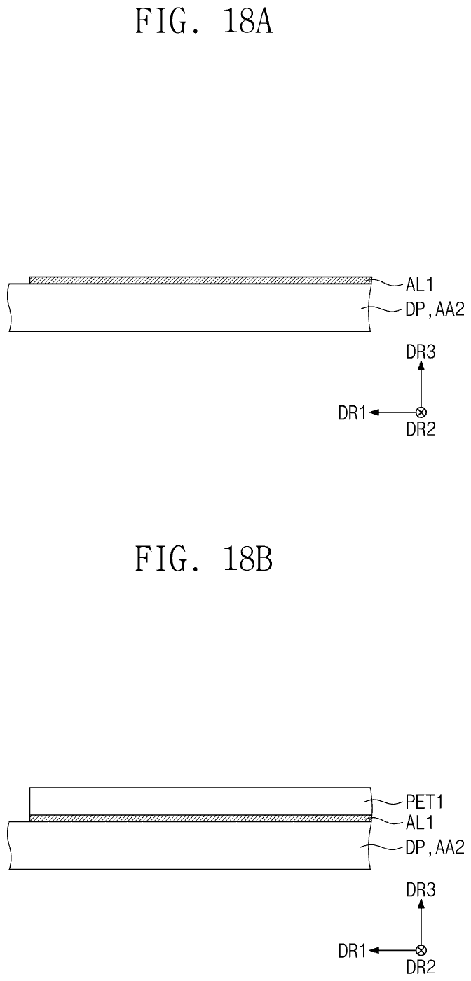

FIG. 16 is a cross-sectional view taken along line III-III′ illustrated in FIG. 12 according to an embodiment of the disclosure.

Referring to FIG. 16, an embodiment of an IC cover layer C-IC-2 may include a first insulating tape TAP1-2, a conductive tape CTP-2, and a second insulating tape TAP2-2.

The first insulating tape TAP1-2 may be disposed on the display panel DP. The first insulating tape TAP1-2 may include a first adhesive layer AL1-2 and a first base layer PET1-2. The first base layer PET1-2 may be disposed on the display panel DP. The first adhesive layer AL1-2 may be disposed between the display panel DP and the first base layer PET1-2. The first base layer PET1-2 may be attached to the display panel DP by the first adhesive layer AL1-2.

The conductive tape CTP-2 may be disposed on the first insulating tape TAP1-2. The conductive tape CTP-2 may include a second adhesive layer AL2-2, a conductive layer CTL-2, and a first coating layer CT1-2.

The conductive layer CTL-2 may be disposed on the first base layer PET1-2. The second adhesive layer AL2-2 may be disposed between the first base layer PET1-2 and the conductive layer CTL-2. The conductive layer CTL-2 may be attached to the first base layer PET1-2 by the second adhesive layer AL2-2.

The first coating layer CT1-2 may be defined on the conductive layer CTL-2 to protect the upper surface of the conductive layer CTL-2. In an embodiment, for example, since the first coating layer CT1-2 covers the upper surface of the conductive layer CTL-2, the corrosion of the upper surface of the conductive layer CTL-2 may be protected by the first coating layer CT1-2. The first coating layer CT1-2 may have a black color.

The second insulating tape TAP2-2 may be disposed on the conductive tape CTP-2. The first insulating tape TAP1-2 and the conductive tape CTP-2 may extend more outwardly than the second insulating tape TAP2-2. The edges of the first insulating tape TAP1-2 and the conductive tape CTP-2 may overlap each other. When viewed in the second direction DR2, the second insulating tape TAP2-2 may be formed to be stepped from the first insulating tape TAP1-2 and the conductive tape CTP-2.

The second insulating tape TAP2-2 may include a third adhesive layer AL3-2, a second base layer PET2-2, and a second coating layer CT2-1. The second base layer PET2-2 may be disposed on the first coating layer CT1-2. The third adhesive layer AL3-2 may be disposed between the second base layer PET2-2 and the conductive layer CTL-2. The second base layer PET2-2 may be attached to the conductive layer CTL-2 by the third adhesive layer AL3-2.

The second coating layer CT2-1 may be disposed on the second base layer PET2-2. The recognition pattern QR may be defined in the second coating layer CT2-1. The second coating layer CT2-1 may have a black color. The second coating layer CT2-1 may be matte to minimize light reflection.

A first opening OP1-1 may be defined in the conductive layer CTL-2 and the first coating layer CT1-2. The first opening OP1-1 may overlap the recognition pattern QR. The area of the first opening OP1-1 may be defined to be larger than the area of the recognition pattern QR.

In a case where a layer having a black color is disposed under the recognition pattern QR that includes a QR code formed in a black pattern, the QR code may not be recognized. In an embodiment of the disclosure, since the first opening OP1-1 overlapping the recognition pattern QR is defined or formed in the first coating layer CT1-2, a layer having a black color may not be disposed under the recognition pattern QR. Accordingly, the recognition pattern QR may be easily recognized.

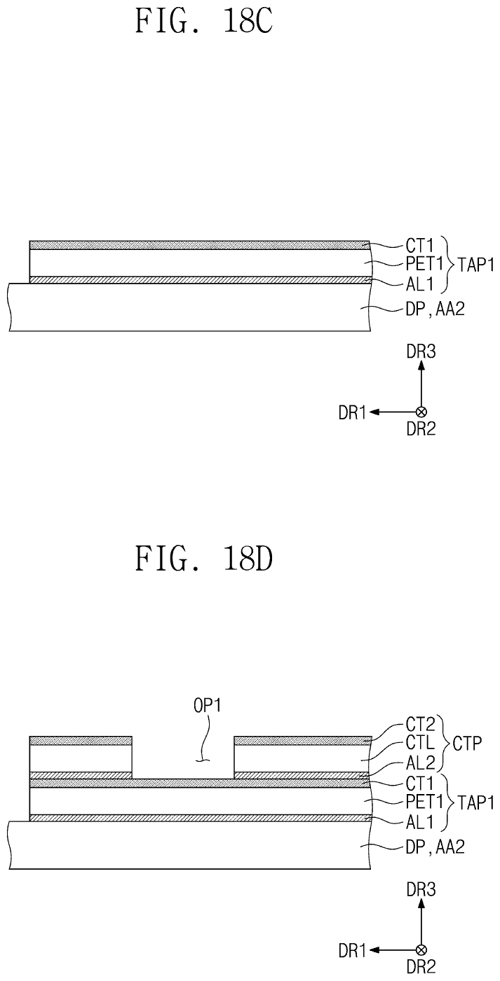

FIG. 17 is a cross-sectional view taken along line III-III′ illustrated in FIG. 12 according to an embodiment of the disclosure.

Referring to FIG. 17, an embodiment of an IC cover layer C-IC-3 may include a first insulating tape TAP1-3, a conductive tape CTP-3, and a second insulating tape TAP2-3.

The first insulating tape TAP1-3 may be disposed on the display panel DP. The first insulating tape TAP1-3 may include a first adhesive layer AL1-3 and a first base layer PET1-3. The first base layer PET1-3 may be disposed on the display panel DP. The first adhesive layer AL1-3 may be disposed between the display panel DP and the first base layer PET1-3. The first base layer PET1-3 and the display panel DP may be attached to each other by the first adhesive layer AL1-3.

The conductive tape CTP-3 may be disposed on the first insulating tape TAP1-3. The conductive tape CTP-3 may include a second adhesive layer AL2-3, a conductive layer CTL-3, and a first coating layer CT1-3.

The conductive layer CTL-3 may be disposed on the first base layer PET1-3. The second adhesive layer AL2-3 may be disposed between the first base layer PET1-3 and the conductive layer CTL-3. The conductive layer CTL-3 and the first base layer PET1-3 may be attached to each other by the second adhesive layer AL2-3.

The first coating layer CT1-3 may be disposed on the conductive layer CTL-3. The first coating layer CT1-3 may protect the conductive layer CTL-3. The first coating layer CT1-3 may have a black color. A first opening OP1-2 may be defined in the first coating layer CT1-3.

The second insulating tape TAP2-3 may be disposed on the conductive tape CTP-3. In an embodiment, as shown in FIG. 17, the second insulating tape TAP2-3, the first insulating tape TAP1-3, and the conductive tape CTP-3 may have areas equal to each other when viewed on a plane.

The second insulating tape TAP2-3 may include a third adhesive layer AL3-3, a second base layer PET2-3, and a second coating layer CT2-2. The second base layer PET2-3 may be disposed on the conductive layer CTL-3.

The second coating layer CT2-2 may be disposed on the second base layer PET2-3. The recognition pattern QR may be defined in the second coating layer CT2-2. The second coating layer CT2-2 may have a black color to improve the recognition rate of the recognition pattern QR. The second coating layer CT2-2 may be matte to minimize light reflection. The recognition pattern QR may overlap the first opening OP1-2. The area of the first opening OP1-2 may be defined to be larger than the area of the recognition pattern QR.

In a case where the first coating layer CT1-3 is disposed under the recognition pattern QR, the recognition pattern QR formed in a black pattern may not be recognized. In an embodiment of the disclosure, since a portion of the first coating layer CT1-3 that overlaps the recognition pattern QR is removed, a layer having a black color may not be disposed under the recognition pattern QR. Accordingly, the recognition pattern QR may be recognized more easily.

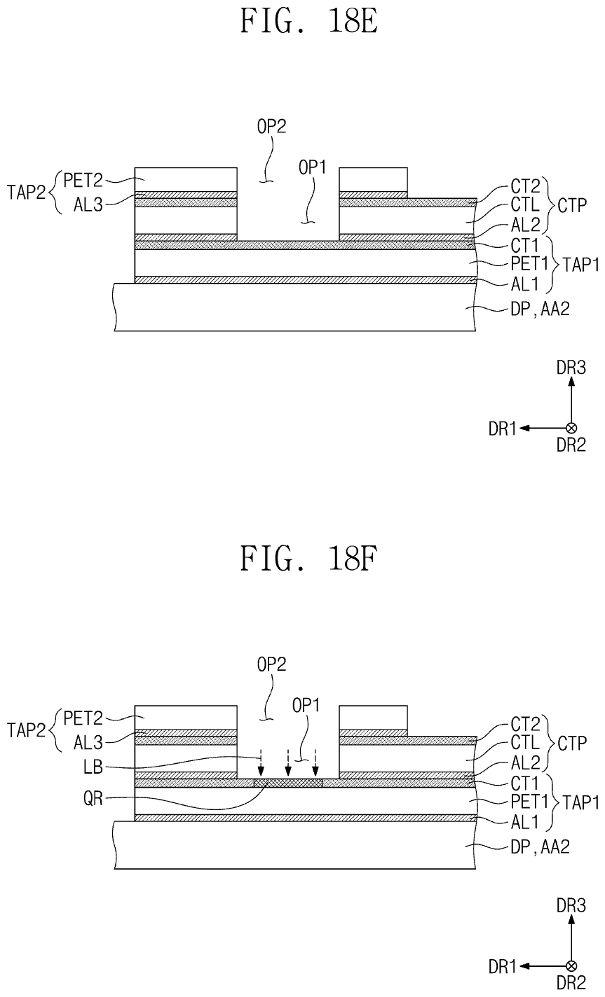

FIGS. 18A to 18F are views illustrating a manufacturing method of the display device according to an embodiment of the disclosure.

For convenience of illustration and description, for example, in FIGS. 18A to 18F, the printed circuit board PCB may be omitted.

In an embodiment of a manufacturing method of the display device, as shown in FIG. 11 and FIGS. 18A to 18F, the first area AA1, the second area AA2 on which the data driver DDV is disposed, and the display panel DP including the bending area BA between the first area AA1 and the second area AA2 may be prepared. The IC cover layer C-IC may be provided on the data driver DDV. The IC cover layer C-IC may be disposed on the second area AA2. Hereinafter, the manufacturing processes of the IC cover layer C-IC will be described in detail with reference to FIGS. 18B to 18F.

Referring to FIG. 18B, the first adhesive layer AL1 and the first base layer PET1 may be provided (or formed) on the second area AA2 of the display panel DP. In an embodiment, the first adhesive layer AL1 may be provided on the second area AA2, and the first base layer PET1 may be provided on the first adhesive layer AL1.

Referring to FIG. 18C, the first coating layer CT1 having a black color may be provided on the first base layer PET1. Accordingly, the first insulating tape TAP1 including the first adhesive layer AL1, the first base layer PET1, and the first coating layer CT1 may be provided on the second area AA2 of the display panel DP.

Referring to FIG. 18D, the conductive tape CTP in which the first opening OP1 is defined may be provided on the first coating layer CT1. In an embodiment, the second adhesive layer AL2 in which the first opening OP1 is defined may be provided on the first coating layer CT1, and the conductive layer CTL in which the first opening OP1 is defined may be provided on the first coating layer CT1. In addition, the second coating layer CT2 which has a black color and in which the first opening OP1 is defined may be provided on the conductive layer CTL.

Referring to FIG. 18E, the second insulating tape TAP2 in which the second opening OP2 overlapping the first opening OP1 is defined may be provided on the conductive tape CTP. In an embodiment, the third adhesive layer AL3 in which the second opening OP2 is defined may be provided on the second coating layer CT2, and the second base layer PET2 in which the second opening OP2 is defined may be provided on the third adhesive layer AL3.

Referring to FIG. 18F, a laser beam LB may be provided to the first coating layer CT1 through the first opening OP1 and the second opening OP2 to form the recognition pattern QR. Since the laser beam LB removes a predetermined portion of the first coating layer CT1, the recognition pattern QR with a QR code may be formed or defined in the first coating layer CT1. Accordingly, the recognition pattern QR overlapping the first opening OP1 and the second opening OP2 may be defined in the first coating layer CT1.

The first opening OP1 and the second opening OP2 may provide space for providing the laser beam LB. Since each of the first opening OP1 and the second opening OP2 is defined to have a larger area than the recognition pattern QR, the laser beam LB may be easily provided to an area for defining the recognition pattern QR.

According to an embodiment of the disclosure, an opening is defined on the recognition pattern, such that the recognition pattern may be exposed to the outside through the opening. Accordingly, the recognition pattern may be provided without providing any separate structure.

In addition, by removing a portion of a black coating layer disposed under the recognition pattern, the recognition pattern may be recognized more easily.

In addition, by disposing a transparent insulating layer between the recognition pattern and the conductive layer, a black coating layer is not disposed under the recognition pattern, so the recognition pattern may be recognized more easily. In addition, since a transparent insulating layer is disposed on the conductive layer, the upper surface of the conductive layer is not exposed to the outside by the transparent insulating layer, thereby effectively preventing the corrosion of the conductive layer.

The invention should not be construed as being limited to the embodiments set forth herein. Rather, these embodiments are provided so that this disclosure will be thorough and complete and will fully convey the concept of the invention to those skilled in the art.

In the disclosure, the display device include an electronic device including a display screen. That is, embodiments of the invention may be applied to any display device or any electronic device including a display screen, for example, a mobile phone, a smart phone, a tablet computer, a digital television (TV), a three-dimensional (3D) TV, a personal computer (PC), a home appliance, a laptop computer, a personal digital assistant (PDA), a portable multimedia player (PMP), a digital camera, a music player, a portable game console, a navigation device, etc.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a first area, a second area, and a bending area between the first area and the second area;
a driving integrated circuit disposed on the second area; and
an integrated circuit cover layer disposed on the driving integrated circuit,
wherein the integrated circuit cover layer includes;
a first insulating tape;
a second insulating tape disposed on the first insulating tape; and
a conductive tape disposed between the first insulating tape and the second insulating tape, and
a recognition pattern is defined in one of the first insulating tape and the second insulating tape.

2. The display device of claim 1, wherein the recognition pattern includes a quick response pattern.

3. The display device of claim 1, wherein the first insulating tape includes:
a first base layer; and
a first coating layer disposed on the first base layer,
wherein the recognition pattern is defined in the first coating layer.

4. The display device of claim 3, wherein a first opening overlapping the recognition pattern is defined in the conductive tape.

5. The display device of claim 4, wherein a second opening overlapping the recognition pattern is defined in the second insulating tape.

6. The display device of claim 5, wherein when viewed on a plane, each of the first opening and the second opening has a larger area than the recognition pattern.

7. The display device of claim 3, wherein the conductive tape includes:
a conductive layer disposed on the first insulating tape; and
a second coating layer disposed on the conductive layer.

8. The display device of claim 7, wherein each of the first coating layer and the second coating layer has a black color.

9. The display device of claim 7, wherein the first insulating tape further includes a first adhesive layer disposed between the second area and the first base layer, and
the conductive tape further includes a second adhesive layer disposed between the conductive layer and the first coating layer.

10. The display device of claim 9, wherein the second insulating tape includes:
a second base layer; and
a third adhesive layer disposed between the second base layer and the second coating layer.

11. The display device of claim 1, wherein the first insulating tape and the conductive tape extend further outward than the second insulating tape.

12. The display device of claim 1, wherein
the conductive tape includes:
a conductive layer disposed on the first insulating tape; and
an insulating layer disposed between the conductive layer and the second insulating tape,
wherein the second insulating tape includes:
a base layer; and
a coating layer disposed on the base layer,
wherein the recognition pattern is defined in the coating layer.

13. The display device of claim 1, wherein the conductive tape includes:
a conductive layer disposed on the first insulating tape; and
a first coating layer disposed on the conductive layer, and
wherein the second insulating tape includes:
a base layer; and
a second coating layer disposed on the base layer, wherein the recognition pattern is defined in the second coating layer.

14. The display device of claim 13, wherein an opening overlapping the recognition pattern is defined in the conductive layer and the first coating layer.

15. The display device of claim 13, wherein an opening overlapping the recognition pattern is defined in the first coating layer.

16. A manufacturing method of a display device, the manufacturing method comprising:
preparing a display panel including a first area, a second area on which a driving integrated circuit is disposed, and a bending area between the first area and the second area; and
providing an integrated circuit cover layer on the driving integrated circuit,
wherein the providing the integrated circuit cover layer includes:
providing a first base layer on the second area;
providing a first coating layer on the first base layer;
providing a conductive tape, in which a first opening is defined, on the first coating layer;
providing a second insulating tape, in which a second opening overlapping the first opening is defined, on the conductive tape; and
forming a recognition pattern, which overlaps the first opening and the second opening, in the first coating layer.

17. The manufacturing method of claim 16, wherein the forming the recognition pattern includes providing a laser beam to the first coating layer through the first opening and the second opening.

18. The manufacturing method of claim 16, wherein when viewed on a plane, each of the first opening and the second opening has a larger area than the recognition pattern of the first coating layer.

19. The manufacturing method of claim 16, wherein the recognition pattern includes a quick response pattern.

20. An electronic device comprising:
a display panel including a first area, a second area, and a bending area between the first area and the second area;
a driving integrated circuit disposed on the second area; and
an integrated circuit cover layer disposed on the driving integrated circuit,
wherein the integrated circuit cover layer includes;
a first insulating tape;
a second insulating tape disposed on the first insulating tape; and
a conductive tape disposed between the first insulating tape and the second insulating tape, and
a recognition pattern is defined in one of the first insulating tape and the second insulating tape.
